(19) United States
(12) Patent Application Publication
(10) Pub. No.: US 2011/0298121 A1
(43) Pub. Date: Dec. 8, 2011

(54) POWER SEMICONDUCTOR DEVICE

(75) Inventors: Hiroshi Nishibori, Tokyo (JP); Toshiaki Shinohara, Tokyo (JP); Tatsuo Oota, Tokyo (JP)

(73) Assignee: MITSUBISHI ELECTRIC CORPORATION, Chiyoda-ku (JP)

(21) Appl. No.: 13/027,582

(22) Filed: Feb. 15, 2011

(30) Foreign Application Priority Data
Jun. 2, 2010 (JP) 2010-127034

(51) Int. Cl. H01L 23/373; H01L 23/49

(52) U.S. Cl. 257/713; 257/784; 257/E23.11; 257/E23.024

(57) ABSTRACT

A power semiconductor device according to the present invention includes a heat sink made of Cu and having a thickness of 2 to 3 mm, an insulating substrate bonded on the heat sink with interposition of a first bonding layer (under-substrate solder), and a power semiconductor element mounted on the insulating substrate. In the heat sink, a buffer slot is formed at a periphery of a region bonded to the insulating substrate.

### BACKGROUND OF THE INVENTION

1. Field of the Invention

The present invention relates to a power semiconductor device having a configuration in which a power semiconductor element is bonded to a metal circuit pattern of an insulating substrate by a solder material or the like, and moreover a back surface metal pattern of the insulating substrate is bonded to a heat sink by a solder material or the like.

2. Description of the Background Art

Japanese Patent Application Laid-Open No. 7-202088 (1995) discloses a power semiconductor device having a configuration in which an insulating substrate having a semiconductor element mounted thereon is installed on a metal base plate serving as a heat dissipation plate and then soldered, with which a resin casing, an external lead terminal, and the like, are combined.

In a reliability evaluation test for evaluating reliability against a thermal stress of a power semiconductor device for the general industry having such a configuration, for example, a heat cycle test is performed in which the ambient environment temperature is changed without supplying current to a power semiconductor element and fatigue resistance characteristics of a solder provided below an insulating substrate are examined. In the heat cycle test, the temperature change conditions are set to be −40 to 125° C.

Additionally, a power cycle test is performed in which current is intermittently supplied to a power semiconductor element without changing the ambient environment temperature and fatigue resistance characteristics of an Al-wire bonding portion provided on the power semiconductor element, a solder provided below the power semiconductor element, and the like, are mainly examined. In the power cycle test, the maximum temperature of the power semiconductor element is limited to 125° C., and the load conditions are set such that a difference in the temperature of the power semiconductor element between when current is supplied and when current is not supplied can be kept constant.

However, the temperature conditions in these tests have become severer in order to respond to recent downsizing of a power semiconductor device and adoption of a high heat-resistance element. Thus, the temperature change conditions in the heat cycle test are shifting from a range of −40 to 125° C. to a range of −40 to 150° C., and the maximum temperature of a power semiconductor element in the power cycle test is shifting from 125° C. to 175° C. In a power semiconductor device used in such a high-temperature environment, there has been a problem that cracking occurs in a solder bonding portion between a power semiconductor element and an insulating substrate and in an Al-wire bonding portion of the power semiconductor element at an early stage, so that a lifetime (reliability) conventionally required cannot be obtained.

### SUMMARY OF THE INVENTION

An object of the present invention is to provide a power semiconductor device causing no cracking in a bonding portion around a power semiconductor element and in a bonding portion between an insulating substrate and a heat sink, even under high-temperature load conditions.

A first power semiconductor device according to the present invention includes a heat sink, an insulating substrate, and a power semiconductor element. The heat sink is made of Cu, and has a thickness of 2 to 3 mm. The insulating substrate is bonded on the heat sink with interposition of a first bonding layer. The power semiconductor element is mounted on the insulating substrate. In the heat sink, a slot is formed at a periphery of a region bonded to the insulating substrate.

By reducing the thickness of the heat sink to 2 to 3 mm which is smaller than the thickness of a conventional heat sink, a strain of the first bonding layer is reduced. Additionally, by forming the slot in the heat sink, a deflection which may be caused by the reduction in the thickness of the heat sink is suppressed.

A second power semiconductor device according to the present invention includes an insulating substrate, a power semiconductor element, a buffer plate, and an Al wire. The power semiconductor element is bonded on the insulating substrate with interposition of a bonding layer. The buffer plate is provided on the power semiconductor element. The Al wire is bonded on the buffer plate, for electrical wiring. The linear expansion coefficient of the buffer plate is intermediate between that of the Al wire and that of the power semiconductor element.

Due to the buffer plate whose linear expansion coefficient is intermediate between that of the Al wire and that of the power semiconductor element, a stress applied to a bonding portion of the Al wire can be reduced, and thus reliability is improved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a power semiconductor device according to an assumption technique of the present invention;

FIG. 2 is a cross-sectional view of a power semiconductor device according to a preferred embodiment 1;

FIG. 3 is a plan view showing an insulating substrate and a circuit pattern;

FIG. 4 is a cross-sectional view showing a configuration of the insulating substrate;

FIG. 5 is an enlarged view showing a dimple of the circuit pattern;

FIG. 6 is a plan view showing a buffer slot of a heat sink;

FIG. 7 is a plan view showing a buffer slot of the heat sink;

FIG. 8 is a plan view showing a buffer slot of the heat sink;

FIG. 9 is a cross-sectional view of a power semiconductor device according to a preferred embodiment 2;

FIG. 10 is a cross-sectional view showing a configuration of a buffer plate;

FIG. 11 is a cross-sectional view showing a configuration of the buffer plate;

FIG. 12 is a cross-sectional view showing a configuration of the buffer plate; and

FIG. 13 is a plan view showing shapes of the buffer plate.

### DESCRIPTION OF THE PREFERRED EMBODIMENTS

### Assumption Technique

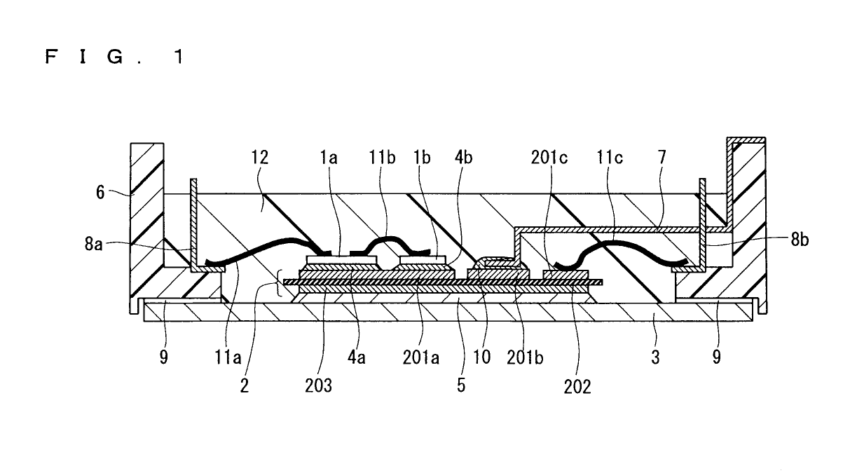

FIG. 1 shows a cross-sectional view of a power semiconductor device according to an assumption technique of the present invention. Power semiconductor elements 1a, 1b are bonded to a circuit pattern 201a of an insulating substrate 2 with interposition of solders 4a, 4b provided below the elements. Circuit patterns 201a, 201b, 201c each made of a Cu material and having a thickness of 0.25 to 0.3 mm are formed on a surface of an aluminum-nitride (AlN) base member 202 made of ceramic and having a thickness of 0.635 mm. A back-surface pattern 203 made of the same material and having the same thickness as those of the circuit pattern 201 is formed on a back surface of the AlN base member 202. These are bonded in advance by an Ag, Cu, Ti-based active metal brazing material, to constitute the insulating substrate 2.

The back-surface pattern 203 of the insulating substrate 2 is bonded to a heat sink 3 made of a Cu material and having a thickness of 4 mm, with interposition of an under-substrate solder 5. A resin casing 6 is bonded to the heat sink 3 with an adhesive 9 so as to surround the insulating substrate 2 and the power semiconductor elements 1a, 1b formed thereon. An electrode terminal 7 and signal terminals 8a, 8b are mounted on the resin casing 6. The electrode terminal 7 is bonded to the circuit pattern 201b with a terminal-attached solder 10. The power semiconductor element 1a and the signal terminal 8a are wired to each other by an aluminum wire 11a. The power semiconductor element 1a and the power semiconductor element 1b are wired to each other by an aluminum wire 11b. The circuit pattern 201c and the signal terminal 8b are wired to each other by an aluminum wire 11c. The interior of the resin casing 6 is sealed with a sealing resin 12 such as a silicone gel or an epoxy resin. A control substrate having an electronic component mounted thereon for electrically controlling the power semiconductor device, is not shown.

When a heat cycle load is applied to the power semiconductor device having the above-mentioned configuration, a strain occurs in the under-substrate solder 5 due to mismatch between the apparent linear expansion coefficient (α is nearly equal to 7 ppm) of the insulating substrate 2 and the linear expansion coefficient (α=17 ppm) of the heat sink 3 made of the Cu material. In accordance with the process of the heat cycle load, very small cracking occurs, and the cracking progresses to hinder dissipation of heat of the power semiconductor element, and finally break the power semiconductor elements 1a, 1b. Here, in heat-cycle temperature change conditions of −40 to 125° C., a structure which satisfies a reliability-guaranteeing life cycle is designed for preventing the above-described phenomenon. However, it has been found that when setting of the temperature change conditions in the heat cycle test is changed from a range of −40 to 125° C. to a range of −40 to 150° C., a strain in the under-substrate solder based on an analysis increases by about 45% and in accordance with the increase of the strain, a reliability life is shortened to about 1/10 or less in an actual evaluation, too.

Additionally, in bonding portions between the power semiconductor element 1a and the aluminum wires 11a, 11b, a thermal stress also occurs based on mismatch (Δα is nearly equal to 19 ppm) between the linear expansion coefficient (α is nearly equal to 4 ppm) of the power semiconductor element 1a and the linear expansion coefficient (α is nearly equal to 23 ppm) of the aluminum wires 11a, 11b which is caused due to the heat load of the heat cycle. Thus, very small cracking progresses. A structure which satisfies necessary life-cycle guaranteeing reliability is designed so as not to cause the above-described phenomenon in a case where the maximum temperature of the power semiconductor element 1a in the power cycle test is limited to 125° C. However, it has been found that if the maximum temperature is shifted from 125° C. to a severer temperature of 175° C., the life of the bonding portions between the aluminum wires 11a, 11b and the power semiconductor element 1a is shortened to about ¼.

Thus, in the present invention, various devices have been made for maintaining a reliability life of the device even in high-temperature load conditions.

### Preferred Embodiment 1

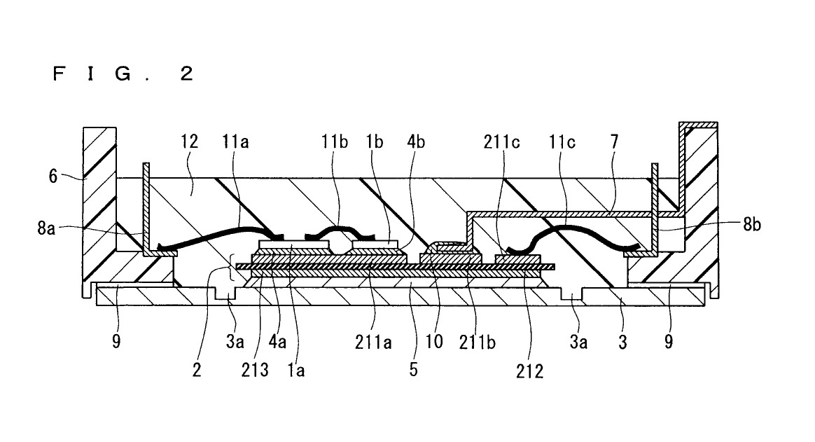

FIG. 2 shows a configuration of a power semiconductor device according to the preferred embodiment 1. The same component parts as those of the power semiconductor device according to the assumption technique shown in FIG. 1 are denoted by the same corresponding reference numerals. The power semiconductor device of this preferred embodiment includes the power semiconductor elements 1a, 1b, an insulating substrate 2 to which the power semiconductor elements 1a, 1b are bonded with interposition of under-element solders 4a, 4b, respectively, and the heat sink 3 to which the insulating substrate 2 is bonded with interposition of the under-substrate solder 5.

The insulating substrate 2 includes an Si₃N₄ base member 212 which is an insulating base member, a back-surface pattern 213 made of Cu and provided on a back surface of the Si₃N₄ base member 212, and circuit patterns 211a, 211b, 211c made of Cu with the same thickness as that of the back-surface pattern 213 and provided on a surface of the Si₃N₄ base member 212. These are bonded in advance by an Ag, Cu, Ti-based active metal brazing material, to constitute the insulating substrate 2.

The back-surface pattern 213 of the insulating substrate 2 is bonded to a heat sink 3 made of Cu, with interposition of an under-substrate solder 5. A resin casing 6 is bonded to the heat sink 3 by an adhesive 9 so as to surround the insulating substrate 2 and the power semiconductor elements 1a, 1b. An electrode terminal 7 and signal terminals 8a, 8b are mounted on the resin casing 6. The electrode terminal 7 is bonded to the circuit pattern 201b by a terminal-attached solder 10. The power semiconductor element 1a and the signal terminal 8a are wired to each other by an aluminum wire 11a. The power semiconductor element 1a and the power semiconductor element 1b are wired to each other by an aluminum wire 11b. Instead, an aluminum ribbon, a Cu wire, an Al—Cu clad ribbon, or the like, may be adopted as a wiring material. The circuit pattern 201c and the signal terminal 8b are wired to each other by an aluminum wire 11c. The interior of the resin casing 6 is sealed with a sealing resin 12 such as a silicone gel or an epoxy resin. A control substrate having an electronic component mounted thereon for electrically controlling the power semiconductor device, is not shown.

<Insulating Substrate>

In this preferred embodiment, the Si₃N₄ base member 212 is used as the insulating base member of the insulating substrate 2. The Si₃N₄ base member 212 has a transverse rupture strength of about 600 Mpa, which is twice the transverse rupture strength of about 300 Mpa of the conventional aluminum nitride (AlN) base member 202. The Si₃N₄ base member 212 has a thickness of the 0.25 to 0.35 mm, which is smaller than the 0.635 mm thickness of the conventional AlN base member 202. On the other hand, each of the circuit patterns 211a, 211b, 211c and the back-surface pattern 213 has a thickness of 0.35 to 0.45 mm, which is larger than the 0.25 to 0.3 mm thickness of the conventional circuit patterns 201a, 201b, 201c and the back-surface pattern 203. Thereby, the linear expansion coefficient as a whole is increased from about 7 ppm to about 10 ppm, and thus brought closer to the linear expansion coefficient 17 ppm of the heat sink 3.

The Si₃N₄ base member 212 has a thermal conductivity of about 90 W/m·K, which is about one-half smaller than the about 180 W/m·K thickness of the conventional AlN base member 202. However, the heat resistance of the Si₃N₄ base member 212 is equivalent to that of the conventional AlN base member 202 because the thickness of the Si₃N₄ base member 212 is one half of the conventional AlN base member 202.

Since each of the circuit patterns 211a, 211b, 211c has the same thickness as that of the back-surface pattern 213, the relationship of (the volume of the circuit patterns 211a, 211b, 211c)≦(the volume of the back-surface pattern 213) is established. Thus, in heating, the insulating substrate 2 is deflected in a direction such that the insulating substrate 2 forms a concave at the side close to the circuit patterns 211a, 211b, 211c. This enables air bubbles (voids) in the under-substrate solder 5 generated in soldering to be easily discharged.

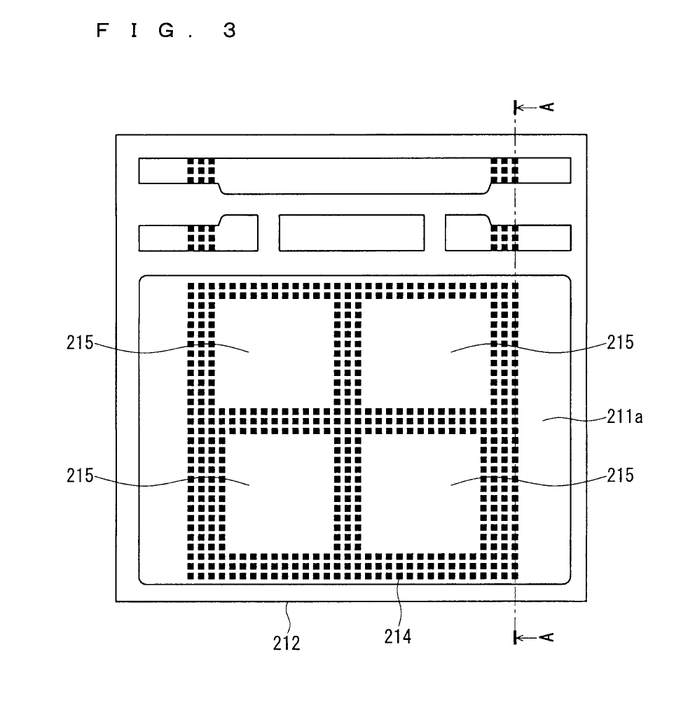

FIG. 3 is a plan view showing the Si₃N₄ base member 212 of the insulating substrate 2 and the circuit pattern 211a bonded thereon. FIG. 4 is a cross-sectional view as taken along the line A-A of FIG. 3. FIG. 5 is an enlarged view of the part B of FIG. 4. As shown in FIG. 3, dimples 214 are formed around surfaces 215 of the circuit pattern 211a on which the power semiconductor elements are to be mounted. Working through an etching process or the like is performed such that, in a cross-sectional view, a diameter D₁ of a surface portion of the dimple 214 can be slightly larger than a diameter D₂ of a spherical portion thereof. By providing such dimples 214 in the circuit pattern 211a, adhesion between an epoxy resin 12 and the insulating substrate 2 can be increased due to an anchor effect in a case where the interior of the resin casing 6 is sealed with the epoxy resin 12. Even if cracking occurs in the under-element solders 4a, 4b at a time of a high temperature, opening of the cracking can be prevented and a progress of the cracking is suppressed due to the increase of the adhesion. The linear expansion coefficient of the epoxy resin 12 is set to 12 to 16 ppm which is smaller than the linear expansion coefficient 20 to 26 ppm of the under-element solders 4a, 4b.

<Heat Sink>

Similarly to the assumption technique, a Cu material is used as the heat sink 3. However, the thickness thereof is approximately 2 to 3 mm, which is smaller than the thickness of the conventional heat sink by about 1 to 2 mm, in order to reduce a strain of the under-substrate solder 5 which occurs when a thermal history is received. In the heat sink 3, the buffer slot 3a is arranged so as to be located at a periphery of the insulating substrate 2, to further reduce the strain of the under-substrate solder 5 and additionally suppress a deflection of the heat sink 3 which may be caused by the reduction in the thickness of the heat sink 3.

The size of the buffer slot 3a has a width of 2 to 3 mm and a depth of 1.5 to 2 mm in a range where the buffer slot 3a does not penetrate the heat sink 3. However, details are determined depending not only on the heat sink 3 but also on the size and the structure of peripheral members such as the insulating substrate 2, a reduction target in the strain of the under-substrate solder 5, a reduction target in the deflection of the heat sink 3, and the like. The buffer slot 3a is not formed at an end portion of the heat sink 3 so as to avoid a significant decrease in the bending strength of the heat sink 3.

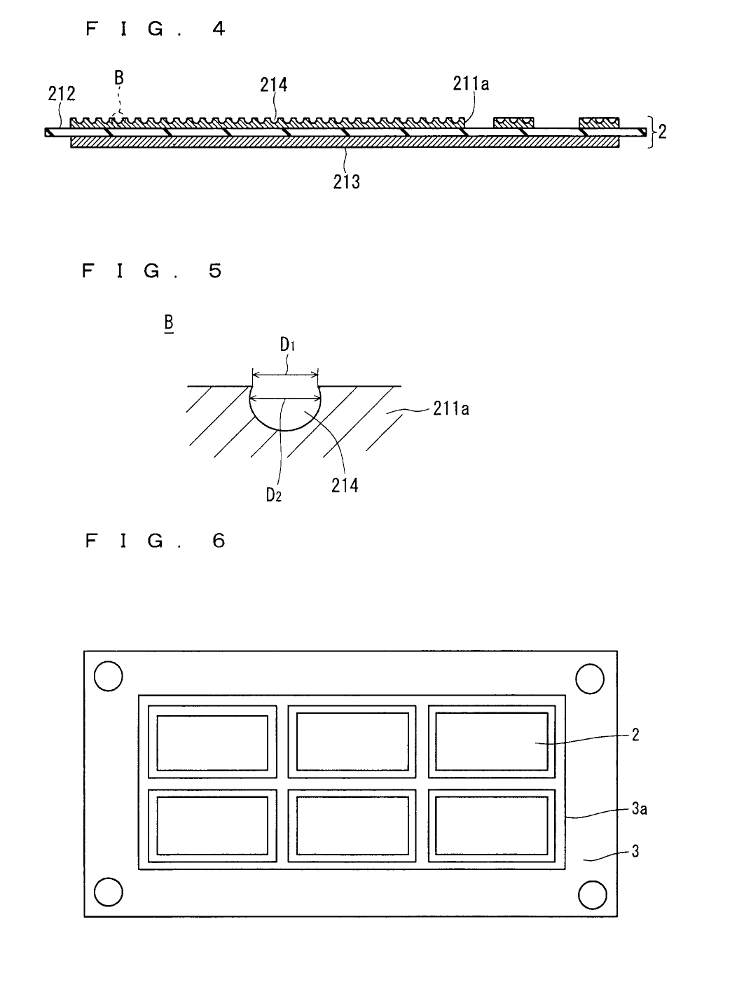

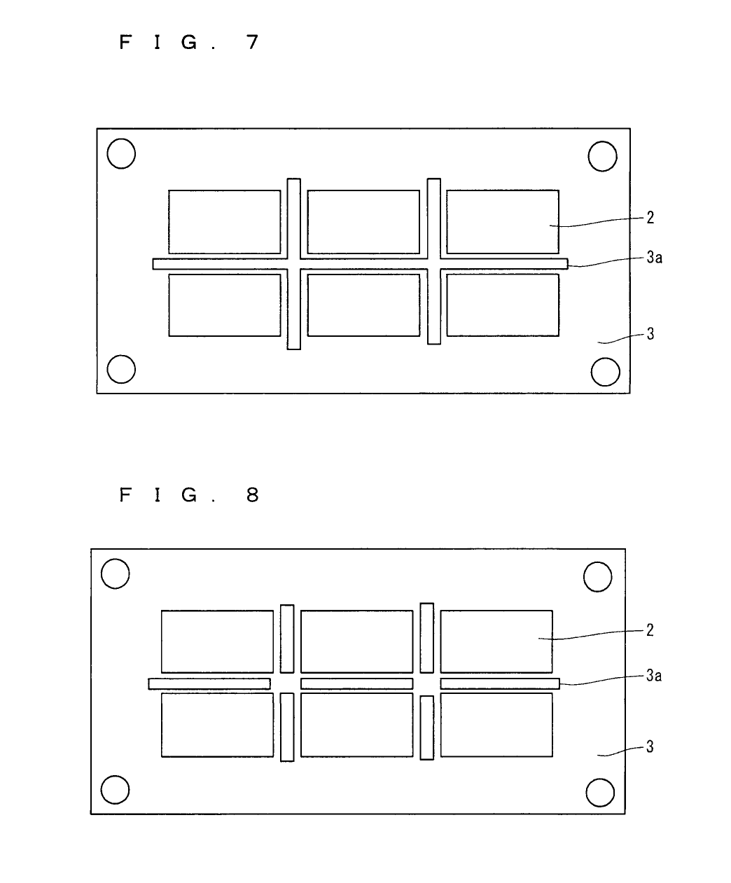

FIGS. 6 to 8 are plan views showing examples of the shape of the buffer slot 3a, on the assumption that six insulating substrates 2 are arranged on the heat sink 3 as shown in FIGS. 6 to 8. The buffer slot 3a may be provided along the outer periphery of the insulating substrate 2 as shown in FIG. 6, or may be provided between the insulating substrates 2 as shown in FIG. 7. Alternatively, the buffer slot 3a may be provided intermittently between the insulating substrates 2 as shown in FIG. 8. The buffer slot 3a is arranged so as not to reach the end portion of the heat sink 3. The buffer slot 3a having any of the shapes can reduce the strain of the under-substrate solder 5 and additionally suppress a deflection of the heat sink 3 which may be caused by the reduction in the thickness of the heat sink 3.

<Effects>

The power semiconductor device of the preferred embodiment 1 provides the following effects. The power semiconductor device of this preferred embodiment includes a heat sink 3 made of Cu and having a thickness of 2 to 3 mm, the insulating substrate 2 bonded on the heat sink 3 with interposition of the under-substrate solder 5 (first bonding layer), and the power semiconductor element 1a mounted on the insulating substrate 2. In the heat sink 3, the buffer slot 3a is formed at a periphery of a bonding region between the heat sink 3 and the insulating substrate 2. By reducing the thickness of the heat sink 3 as compared with the conventional heat sink, the strain of the under-substrate solder 5 is reduced, and furthermore by forming the buffer slot 3a, a deflection of the heat sink 3 which may be caused by the reduction in the thickness of the heat sink 3 is suppressed.

The insulating substrate 2 includes the back-surface pattern 213 made of Cu and bonded to the heat sink 3 with interposition of the under-substrate solder 5, the Si₃N₄ base member 212 formed on the back-surface pattern 213 and serving as the insulating base member, and the circuit patterns 211a, 211b, 211c made of Cu and formed on the Si₃N₄ base member 212. The power semiconductor element 1a is bonded on the circuit patterns 211a, 211b, 211c with interposition of the under-element solder 4a (second bonding layer). The Si₃N₄ base member has a thickness of 0.25 to 0.35 mm. The back-surface pattern 213 and the circuit patterns 211a, 211b, 211c have the same thickness of 0.35 to 0.45 mm. The thickness of the insulating base member is reduced as compared with conventional, and instead the thicknesses of the back-surface pattern 213 and the circuit patterns 211a, 211b, 211c made of Cu are increased, to thereby bring the linear expansion coefficient closer to the linear expansion coefficient of the heat sink 3 made of Cu. Thus, the strain of the under-substrate solder 5 which occurs due to a difference in the linear expansion coefficient therebetween is reduced.

The buffer slot 3a has a width of 2 to 3 mm and a depth of 1.5 to 2 mm in a range where the buffer slot 3a does not penetrate the heat sink 3. By providing the buffer slot 3a having such a size, the deflection of the heat sink 3 is reduced.

Moreover, the power semiconductor device includes the resin casing 6 (outer housing) which is bonded to the heat sink 3 so as to surround the insulating substrate 2 and the power semiconductor element 1a, and the sealing resin 12 which seals the insulating substrate 2 and the power semiconductor element 1a within the resin casing 6. In the circuit patterns 211a, 211b, 211c, the dimples 214 are formed outside the region 215 where the power semiconductor element 1a is bonded. By providing the dimples 214 in the circuit pattern 211a, the adhesion between the epoxy resin 12 and the insulating substrate 2 is increased due to the anchor effect in a case where the interior of the resin casing 6 is sealed with the epoxy resin 12. Thus, even if cracking occurs in the under-element solders 4a, 4b at a time of a high temperature, opening of the cracking can be prevented and a progress of the cracking is suppressed.

### Preferred Embodiment 2

FIG. 9 is a cross-sectional view showing a configuration of a power semiconductor device according to a preferred embodiment 2. The same component parts as those of the power semiconductor device according to the assumption technique shown in FIG. 1 are denoted by the same corresponding reference numerals. In the power semiconductor device of this preferred embodiment, a buffer plate 13 which is bonded on the power semiconductor element 1a with interposition of an under-buffer-plate bonding material 14 is provided in addition to the configuration of the assumption technique.

The buffer plate 13 and the signal electrode 8a are wired to each other by the Al-wire 11a. The buffer plate 13 and the power semiconductor element 1b are wired to each other by the Al-wire 11b. The other parts of the configuration is the same as that of the assumption technique, and therefore a description thereof is omitted. Although the power semiconductor device of this preferred embodiment will be described based on the configuration of the assumption technique, the buffer plate 13 may be provided in the power semiconductor device of the preferred embodiment 1.

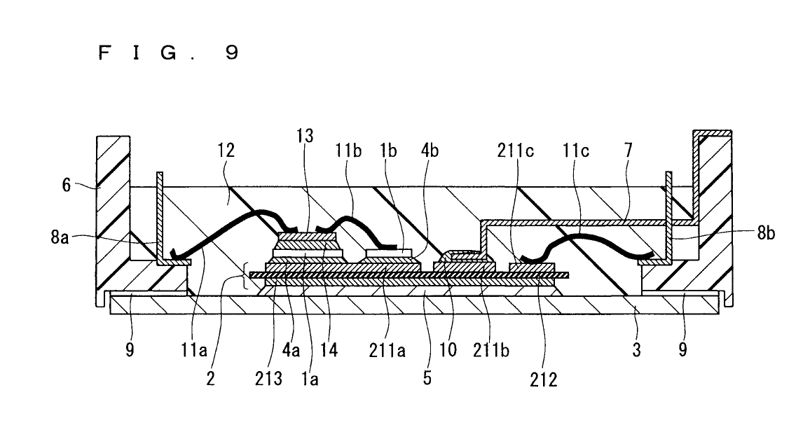

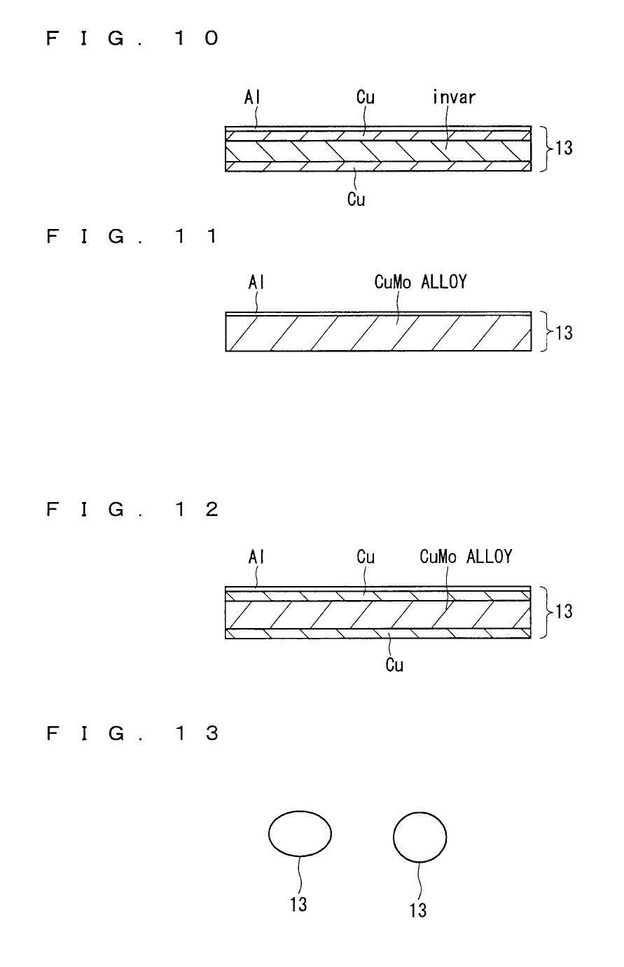

FIGS. 10 to 12 are cross-sectional views showing examples of a configuration of the buffer plate 13. FIG. 13 is a plan view of the buffer plate 13. The buffer plate 13 is made of, for example, a Cu-invar-Cu clad material including invar and Cu foils provided on a surface and a back surface thereof, as shown in FIG. 10. Alternatively, the buffer plate 13 may be formed of a CuMo alloy as shown in FIG. 11, or a Cu—CuMo—Cu clad material including a CuMo alloy and Cu foils provided on a surface and a back surface thereof as shown in FIG. 12.

A surface treatment using plating, physical vapor deposition (PVD), or the like, may be performed on at least a surface side of the stress buffer plate 13, to form an Al thin film or a Ni thin film, thereby improving the bonding with the Al wire 11a. When, for example, a paste of micro-Ag or nano-Ag is used as the under-buffer-plate bonding material 14, the surface treatment is not performed on the back surface so that the Al thin film or the Ni thin film is formed on the surface bonded to the Al wire, because more excellent bonding properties can be obtained if the back surface of the buffer plate 13 is bare. To perform the surface treatment on only a single surface, a masking process for masking a surface needing no plating is required in a case of the plating, but the masking process is not required in a case of the PVD, which is advantageous in terms of costs.

In any of the configurations, the linear expansion coefficient of the buffer plate 13 is selected to be approximately 7 to 13 ppm which is an intermediate value between the linear expansion coefficient of the Al wire 11a (about 23 ppm) and the linear expansion coefficient of the power semiconductor element 1a (about 4 ppm).

The thickness of the buffer plate 13 is reduced so as not to apply a load to the under-buffer-plate bonding material 14, and the thickness of each clad material is set within a range of approximately 0.5 to 1.0 mm in accordance with the target linear expansion coefficient. In a case where the buffer plate 13 is formed of a clad material, the thickness of the clad material is basically made the same as the thickness of a metal material positioned on the surface and the back surface, to suppress a deflection of the buffer plate 13 itself.

By shaping the buffer plate 13 into a circular shape or an oval shape in a plan view as shown in FIG. 13, a thermal stress occurring in the under-buffer-plate bonding material 14 is distributed and reduced, thus providing high reliability to the bonding between the under-buffer-plate bonding material 14 and the power semiconductor element 1a.

In a result obtained by a numerical analysis, when a stress in the bonding portion at which the Al wire 11a is bonded to the power semiconductor element 1a is defined as 1, the use of the buffer plate 13 having a linear expansion coefficient of 7 ppm reduces a stress ratio to 0.7, and the use of the buffer plate having a linear expansion coefficient of 11 ppm reduces the stress ratio to 0.5. As the linear expansion coefficient of the buffer plate 13, the optimum value is selected in consideration of a balance between the reliability life of the bonding portion of the Al wire 11a bonded to the surface of the buffer plate 13 and the reliability life of the bonding material 14 provided on the back surface of the buffer plate 13 for bonding the power semiconductor element 1a.

<Effects>

The power semiconductor device of the preferred embodiment 2 provides the following effects. The power semiconductor device of the preferred embodiment 2 further includes the buffer plate 13 and the Al wire 11a. The buffer plate 13 is formed on the power semiconductor element 1a with interposition of the under-buffer-plate bonding material 14 (third bonding layer). The Al wire 11a is bonded to the buffer plate 13, for electrical wiring. The linear expansion coefficient of the buffer plate 13 is intermediate between that of the Al wire 11a and that of the power semiconductor element 1a. By providing such a buffer plate 13, a stress applied to the bonding portion of the Al wire is reduced, to improve the reliability.

The buffer plate 13 is made of any of the materials Cu—Mo alloy, Cu/invar/Cu, and Cu/Cu—Mo alloy/Cu. The Al or Ni thin film is formed on at least the surface of the buffer plate 13, to thereby improve the bonding with the Al wire 11a.

When the Al or Ni thin film is formed on only one surface of the buffer plate 13, the masking process for masking a surface needing no plating is required in a case of the plating, but the masking process is not required in a case of the PVD, which is advantageous in terms of costs.

In a case where the paste of micro-Ag or nano-Ag is used as the under-buffer-plate bonding layer 14, good bonding properties are obtained when the back surface of the buffer plate 13 is bare without the Al or Ni thin film being formed thereon.

Furthermore, by shaping the buffer plate 13 into a circular shape or an oval shape in a plan view, the thermal stress occurring in the under-buffer-plate bonding material 14 is distributed and reduced, thus providing high reliability to the bonding between the under-buffer-plate bonding material 14 and the power semiconductor element 1a.

The power semiconductor device includes the insulating substrate 2, the power semiconductor element 1a, the buffer plate 13, and the Al wire 11a. The power semiconductor element 1a is bonded on the insulating substrate 2 with interposition of the under-element solder 4 (bonding layer). The buffer plate 13 is bonded on the power semiconductor element 1a with interposition of the under-buffer-plate bonding material 14 (bonding layer). The Al wire 11a is bonded to the buffer plate 13, for electrical wiring. The linear expansion coefficient of the buffer plate 13 is intermediate between that of the Al wire 11a and that of the power semiconductor element 1a. By providing such a buffer plate 13, a stress applied to the bonding portion of the Al wire is reduced, to improve the reliability.

While the invention has been shown and described in detail, the foregoing description is in all aspects illustrative and not restrictive. It is therefore understood that numerous modifications and variations can be devised without departing from the scope of the invention.

What is claimed is:

1. A power semiconductor device comprising:
a heat sink made of Cu and having a thickness of 2 to 3 mm;
an insulating substrate bonded on said heat sink with interposition of a first bonding layer; and
a power semiconductor element mounted on said insulating substrate,
wherein in said heat sink, a slot is formed at a periphery of a region bonded to said insulating substrate.

2. The power semiconductor device according to claim 1, wherein
said insulating substrate comprises:
a back-surface pattern made of Cu and bonded to said heat sink with interposition of said first bonding layer;
a base member made of Si₃N₄ and provided on said back-surface pattern; and
a circuit pattern made of Cu and formed on said base member,
wherein
said power semiconductor element is bonded on said circuit pattern with interposition of a second bonding layer,
said base member has a thickness of 0.25 to 0.35 mm,
said back-surface pattern and said circuit pattern have the same thickness of 0.35 to 0.45 mm.

3. The power semiconductor device according to claim 1, wherein
said slot has a width of 2 to 3 mm and a depth of 1.5 to 2 mm, in a range where said slot does not penetrate said heat sink.

4. The power semiconductor device according to claim 1, further comprising:
a buffer plate provided on said power semiconductor element with interposition of a third bonding layer; and
an Al wire bonded on said buffer plate, for electrical wiring,
wherein the linear expansion coefficient of said buffer plate is intermediate between that of said Al wire and that of said power semiconductor element.

5. The power semiconductor device according to claim 4, wherein
said buffer plate is made of any of materials of Cu·Mo alloy, Cu/invar/Cu, and Cu/Cu·Mo-alloy/Cu, and an Al or Ni thin film is formed on at least a surface of said buffer plate.

6. The power semiconductor device according to claim 5, wherein
said Al or Ni thin film is formed by using a PVD method.

7. The power semiconductor device according to claim 5, wherein
said third bonding layer is a paste of micro-Ag or nano-Ag.

8. The power semiconductor device according to claim 4, wherein
said buffer plate has a circular shape or an oval shape in a plan view.

9. The power semiconductor device according to claim 2, comprising:
an outer housing bonded to said heat sink and surrounding said insulating substrate and said power semiconductor element; and
a sealing resin sealing said insulating substrate and said power semiconductor element within said outer housing,
wherein in said circuit pattern, dimpling is performed in a region outside a region to which said power semiconductor element is bonded.

10. A power semiconductor device comprising:
an insulating substrate;
a power semiconductor element bonded on said insulating substrate with interposition of a bonding layer;
a buffer plate bonded on said power semiconductor element with interposition of a bonding layer; and
an Al wire bonded on said buffer plate, for electrical wiring,
wherein the linear expansion coefficient of said buffer plate is intermediate between that of said Al wire and that of said power semiconductor element.
